(19) United States
(12) Patent Application Publication
(10) Pub. No.: US 2002/0197418 A1
(43) Pub. Date: Dec. 26, 2002

(54) Molecular beam epitaxy effusion cell for use in vacuum thin film deposition and a method therefor

(76) Inventors: Tokio Mizukami, Kanagawa (JP); Tateo Saito, Ibaraki (JP); Junji Kido, Yamagata (JP)

Correspondence Address: FLYNN, THIEL, BOUTELL & TANIS, P.C., 2026 Rambling Road, Kalamazoo, MI, 49008-1699, US

(21) Appl. No.: 10/161,248

(22) Filed: May 31, 2002

(30) Foreign Application Priority Data
Jun. 26, 2001 (JP) 2001-192261

(51) Int. Cl. C23C 16/00

(52) U.S. Cl. 427/596; 118/723 VE; 118/726; 427/248.1; 427/66

(57) ABSTRACT

A molecular beam epitaxy effusion cell, in which effusion material 5 is heated to melt down to be evaporated, so as to generate vapor molecule for growth of a thin film thereof upon a solid body surface, comprises: a crucible 1 for containing the effusion material 5 therein; and a heating means for heating the effusion material 5 contained within the crucible 1, wherein in the crucible 1 is contained heat conduction medium 4, being stable thermally and chemically and having heat conductivity higher than that of the effusion material 5, such as of pyrolytic boron nitride (PBN), together with the effusion material 5.

### BACKGROUND OF THE INVENTION

1. Field of the Invention

The present invention relates to a molecular beam epitaxy effusion cell for use in vacuum thin film deposition and a method therefor, which generates or effuses molecular or atomic beam so as to yield growth of thin film(s) upon the surface of a solid body, by heating the material thereof to melt and evaporate, and in particular, it relates to a molecular beam epitaxy effusion cell, being suitable for the evaporation of the effusion material, such as an organic electro luminescence material or the like, which has a low thermal or heat conductivity.

2. Description of Prior Art

An apparatus for depositing thin films, being called by a molecular beam epitaxy (MBE) apparatus, generally comprises a vacuum chamber that can be brought in high vacuum condition, in which a substrate, such as a semiconductor wafer or the like, is disposed and heated to a desired temperature, and a molecular beam epitaxy effusion cell, such as, the Kunudsen cell, etc., being directed to the surface of the substrate, onto which the thin films are deposited to be grown. The effusion material contained within a crucible of the molecular beam epitaxy effusion cell is heated by a heater, so as to melt down and/or evaporate, and the vapor molecule evaporated thereby is directed onto the surface of the substrate, on which the thin film is to be deposited to grow, thereby forming the film of the effusion material.

In the molecular beam epitaxy effusion cell used in such the thin film depositing or deposition apparatus, the effusion material is stored or contained within the crucible made of PBN (pyrolytic boron nitride) or the like, for example, being high in both thermal and chemical stabilities thereof, and is heated by an electric heater provided around an outside of the crucible, thereby being melted down and evaporated from, so as to generate or effuse the vapor molecule therefrom.

In recent years, researches and developments are made for progress on an organic electro luminescence element (e.g., an organic EL element), in particular, in the technical field of displays and optical communication, etc. Such the organic EL element is an element, in which a light-emitting layer is formed from a material of organic low molecular or organic macromolecular material, having a light-emitting or luminescence function or capacity, and it attracts attentions onto the specific character thereof, as being a self-luminescence element. In the basic structure thereof, for instance, a film of the material for hole transportation, such as tri-phenyl-diamine (TPD) or the like, for example, is formed on a hole injection electrode, on which a fluorescence material, such as aluminum quinolinol complex (Alq₃), etc., is laminated in the form of the light-emitting layer, and further a metal electrode of Mg, Li, Cs, etc., having small work function is formed in the form of an electron injection electrode.

Each of those layers, building up such the organic EL as mentioned above, is formed with using the thin film depositing apparatus, which was mentioned previously. However, the material, especially for use of forming such the organic EL film, is low in the melting or fusing point, as well as, in the heat conductivity thereof. For this reason, when trying to heat and evaporate it by means of such the molecular beam epitaxy effusion cell as mentioned above, although the necessary temperature for evaporation can be obtained in a portion around the crucible in the vicinity of the peripheral wall thereof, where it is heated by the heater, but the temperature comes down to extremely low at the center of the crucible, thereby being brought in the condition that the temperature does not reach to that necessary for the evaporation of the effusion material.

Under such the condition, only the portion of the material contained within the crucible is evaporated, which lies in a part near to the peripheral wall of the crucible, but the material remains in the center of the crucible without evaporating therefrom. For this reason, it brings about, not only a lower yield rate of material(s), but also easily causes defects or the like in the film(s) formed, due to such the unevenness or fluctuation of temperature.

### SUMMARY OF THE INVENTION

According to the present invention, for dissolving such the problem(s) of the molecular beam epitaxy effusion cell related to the conventional art, therefore, an object thereof is to provide a molecular beam epitaxy effusion cell, achieving heat conduction in the crucible with high efficiency, even for such the effusion material of low heat conductivity, such as, the organic EL materials, thereby reducing temperature gradient in the crucible, so that the effusion material is evaporated to generate the vapor molecule evaporated with high efficiency, as well as a method therefor.

For achieving the object mentioned above, according to the present invention, within the crucible 1, not only the effusion material 5, but also heat conduction medium 4 are contained, being stable thermally and chemically and having heat conductivity higher than that of the effusion material. With this, heat from a heater 3 is conducted or transmitted within an inside of the crucible 1 through the heat conduction medium 4, therefore also the effusion material 5 within the crucible 1 can be evaporated with high efficiency.

Namely, a molecular beam epitaxy effusion cell according to the present invention, in which effusion material 5 is heated to melt down to be evaporated, so as to generate vapor molecule for growth of a thin film thereof upon a solid body surface, comprises: a crucible 1 for containing the effusion material 5 therein; and a heating means for heating the effusion material 5 contained within the crucible 1, wherein in the crucible 1 is contained heat conduction medium 4, being stable thermally and chemically and having heat conductivity higher than that of the effusion material 5, together with the effusion material 5.

For instance, as the heat conduction medium 4 is disclosed an example, one made of a high heat conduction material, including at least one of pyrolytic boron nitride (PBN), silicon carbide, and aluminum-nitride, etc.

With such the molecular beam epitaxy effusion cell as mentioned above, the heat conduction medium 4 achieves the function of conducting the heat of the heater 4 into the inside of the crucible 1, even in the case where it is difficult to conduct the heat of the heater 3 into it sufficiently or efficiently, due to the low heat conductivity of the effusion material 5. For this reason, the difference comes to be small in temperature between the vicinity of the peripheral wall and the central portion of the crucible 1, therefore it is also possible to evaporate the effusion material 5 within the inside of the crucible 1, easily.

On the other hand, since the heat conduction medium 4 made of the high heat conduction material, such as pyrolytic boron nitride (PBN), silicon carbide, and aluminum-nitride, etc., is stable thermally and chemically, and since it is hardly evaporated or melted down through heating by means of the heater 3, it is scarcely mixed with the vapor molecule generated and scarcely hardly gives ill influence upon the composition of the film formed. Accordingly, it hardly causes defects in the forming of film(s) with the material(s) to be aimed.

In this manner, with the molecular beam epitaxy effusion cell according to the present invention, since even the effusion material 5 having low heat conductivity can be heated with uniform temperature distribution within the crucible 1, so as to melt down to be evaporated, it is possible to evaporate the effusion material 5 with high yield rate, thereby to grow up the crystal thereof upon the surface of a solid body. With this, it is also possible, not only to rise up utilization ratio of the material(s), but also to improve the quality of the film(s) formed through the growth of crystal without fluctuation in temperature of the effusion material 5.

### BRIEF DESCRIPTION OF THE DRAWINGS

Those and other features, objects and advantages of the present invention will become more apparent from the following description when taken in conjunction with the accompanying drawings wherein:

FIG. 1 is a vertically cross-sectioned side view of a molecular beam epitaxy effusion cell, according to an embodiment of the present invention, in particular for showing the general configuration thereof;

FIG. 2 is a cross-section view of an example of a form of effusion material and heat conduction medium, which are contained in the crucible of the molecular beam epitaxy effusion cell; and

FIG. 3 is a vertically cross-sectioned side view of the molecular beam epitaxy effusion cell, according to another embodiment of the present invention, in particular for showing the general configuration thereof.

### DETAILED DESCRIPTION OF PREFERRED EMBODIMENTS

Hereinafter, embodiments according to the present invention will be fully explained by referring to the attached drawings.

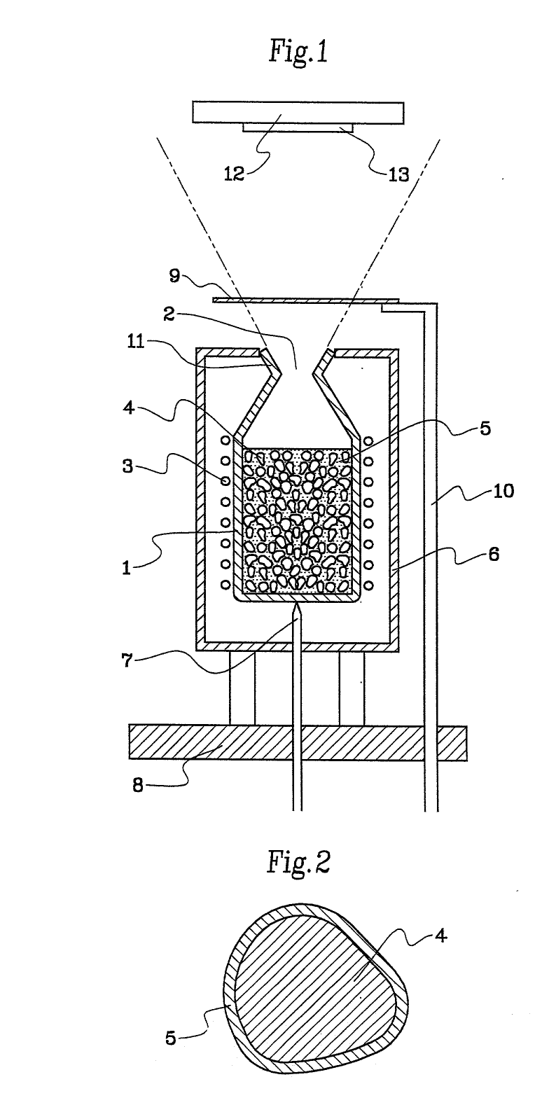

FIG. 1 shows the general configuration of the molecular beam epitaxy effusion cell, according to an embodiment of the present invention. As shown in this figure, it comprises a crucible 1, which has a vapor discharge opening 2 at the top thereof, and a heater 3 provided around the crucible 1 for heating the effusion material 5 to be evaporated, which is contained in an inside thereof. The crucible 1 is made of material, being high in both thermal and chemical stabilities, such the PBN (pyrolytic boron nitride) or the like, for example, as was mentioned above. The crucible 1 shown in this figure is tapered at the vapor discharge opening 2 to be narrowed while being widened gradually toward topside thereof, thereby forming a horn-like draft portion 11 with a taper portion. Thus, a main portion of the crucible 1 below the vapor discharge opening 2 is in a cylindrical shape, into which are contained heat conduction medium 4 and effusion material 5 that will be mentioned later.

In an outside of the heater 3, a reflector 6 is provided for the purpose of reflecting the heat irradiating from the heater 3 back to the side of crucible 1. This reflector 6, and the crucible 1, as well, are provided standing on a flange 8, and through this flange 8 they are attached to a lower port of a vacuum chamber not shown in the figure, therefore the molecular beam epitaxy effusion cell is provided in an inside of the vacuum chamber.

A temperature-measuring juncture of a temperature-measuring element, such as, a thermocouple, for example, is attached onto a bottom surface or on a periphery of the crucible 1, so as to measure the heating temperature of the crucible 1 by means of the heater 3, thereby achieving an observation thereof.

Furthermore on the flange 8, a shutter axis 10 is pivotally supported; therefore the vapor discharge opening 2 of the crucible 1 is opened or closed by a shutter 9 which can rotate around the shutter axis 10.

Opposing the vapor discharge opening 2 of the crucible 1 and putting the shutter 9 therebetween, a substrate 13, such as, a semiconductor wafer, a glass coated with transparent conductive film(s), such as of ITO, etc., is disposed just above it, while being held by a substrate holder 12.

In such the molecular beam epitaxy effusion cell, the effusion material 5 is contained or received within an inside of the crucible 1 therein. Further in this crucible 1, the heat conduction medium 4 in the granular-like form is contained, together with the effusion material 5 mentioned above. This heat conduction medium 4 is stable thermally and chemically, and is made of a material, which has the heat conductivity being higher than that of the effusion material 5. For example, the heat conduction medium 4 may be made of a material of high heat conductivity, such as, the PBN, as same as the crucible 1, or alternatively silicon carbide or aluminum-nitride, etc.

The heat conduction medium 4 is contained while being dispersed within the crucible 1, so that the density thereof comes to be uniform therein. If temperature tends to differ largely between the portion near to the periphery wall of the crucible 1 and the central portion thereof, since the heat conductivity of the effusion material 5 is low, the heat conduction medium 4 should be stuffed densely within the crucible 1. On the other hand, if temperature does not differ so largely between the portion near to the periphery wall of the crucible 1 and the central portion thereof since the heat conductivity of the effusion material 5 is not so low, then the heat conduction medium 4 can be stuffed loosely or roughly within the crucible 1. A volume ratio between the heat conduction medium 4 and the effusion material 5 is selected, in general, to be 70%:30%, or more or less than that.

With such the molecular beam epitaxy effusion cell, when the crucible 1 is heated by the heater 3, the heat conduction medium 4 stuffed therein is heated through the crucible 1, and then the effusion material 5 is indirectly heated through that heat conduction medium 4.

Because the heat conduction medium 4 has the heat conductivity higher than that of the effusion material 5, the heat can be conducted or transmitted up to the center of the crucible 1 by means of the heat conduction medium 4, and then the effusion material 5 is also heated even if being located in the center of the crucible 1, so as to melt down and evaporate therefrom, whereas the heat cannot be transmitted into the center of the crucible if being filled with only the effusion material 5 therein (without the heat conduction medium 4).

Also, the heat conduction medium 4 will not melt down through the heating by means of the heater 3, since it is made of the material, being highly stable thermally and chemically, for example, like PBN as same as the crucible 1. Accordingly, no molecule of material consisting of the heat conduction medium 4 can be included within the vapor molecule of the effusion material 5, which is effused from the vapor effusion opening 2 of the crucible 1, therefore it gives no ill influence upon the composition of the film(s) to be formed through crystal-growth thereof.

However, in a case where the effusion material 5 is of the organic low molecular or the organic macromolecular material, having the EL light-emitting function, the vaporization temperature thereof is greatly lower than that of metal or the like, such as, copper, etc., and is almost equal or lower than 200° C., for example. On the other hand, the thermal decomposition temperature thereof is also relatively low, and for the purpose of evaporation of such the organic low molecular or the organic macromolecular material as mentioned above, it is necessary to heat it by the temperature, being equal or higher than that vaporization temperature and being equal or lower than that thermal decomposition temperature.

The effusion material 5 being heated and vaporized through the heat conduction medium 4 begins evaporation thereof from the surface between the heat conduction medium 4 and the effusion material 5, which are filled within the crucible 1. This evaporation generates gaps or apertures between the heat conduction medium 4, and the vapor molecule evaporated within the inside of the crucible 1 passes through the gaps to go upward, thereby bring about the condition that the vapor molecule is evaporated from the surface of the heat conduction medium 4 filled within the crucible 1. Since the heat conduction medium 4 occupies 70% or more or less in the volume within the crucible 1, the level of the content can be hardly changed within the crucible 1, even if the effusion material 5 evaporates therefrom to be discharged or effused from the crucible 1 as the vapor molecule evaporated. Because of this, the position of that evaporation mentioned above does not goes down in appearance, thereby remaining unchanged. Also, since the heat conduction medium 4 remains within the crucible 1, the reduction is small in the heat capacity thereof even if the effusion material 5 is discharged or effused from the crucible 1 in the form of vapor molecule evaporated.

The vapor molecule of the effusion material 5, being generated by melting or fusing it in this manner, is discharged or effused from the vapor discharge opening 2. Under the condition that the shutter 9 is opened, the vapor molecule discharged from the vapor discharge opening 2 comes fling around and adheres to the surface of the substrate 13, thereby accumulating or forming the thin film(s) thereon.

With the cylindrical-form crucible according to the conventional technology, since also having the discharge opening for the vapor molecule in the cylindrical form, the vapor molecule evaporated therefrom comes up to be extremely high in the density, due to the so-called chimney effect thereof, in particular, in the vicinity of the central axis of the crucible, thereby bringing about a large difference in the thickness of films formed, between the central portion and the peripheral portion of the substrate.

Also, with the crucible formed in a conical shape with the cone-shaped crucible, being proposed for dissolving and/or improving the issue mentioned above, the vapor molecule evaporated is discharged and expanded in its shape along the tapered portion widened upward, therefore it is possible to improve such the unevenness in the film thickness upon the substrate surface. However, when proceeding in the evaporation of the effusion material, both the volume of the effusion material remaining in the crucible and the surface area thereof come down to small, abruptly. Because of this, it is extremely difficult to conduct the control upon temperature and the control upon the manner of evaporation.

On the contrary to this, in accordance with the crucible 1 mentioned by referring to the FIG. 1, having the portion tapered to be narrowed, in particular, in the vapor discharge opening 2 thereof, and also being provided with a draft portion 11 with a taper having a diameter gradually widened or enlarged upward, the vapor molecule evaporated is effused or discharged while being expanding or spreading, when the effusion material is evaporated, as shown by two-dotted chained lines in the FIG. 1. With this, the flow of vapor molecule evaporated and effused from the vapor discharge opening 2 comes almost uniform in the radial direction being orthogonal to the central axis of the crucible 1, therefore it is possible to form the film, to be uniform in the film thickness upon the surface of the substrate 13.

Moreover, since the main body portion of the crucible 1, containing the effusion material 5 and the heat conduction medium 4 therein, is in the cylindrical form, it has no such the defects as the conical form crucible has. Furthermore, as was mentioned previously, since the heat conduction medium 4 is contained within the crucible 1 together with the effusion material 5, the volume of the content remaining unchanged within the crucible 1 in appearance, i.e., the level of the content within the crucible 1 will not lowered nor changed, when the effusion material is evaporated so as to be discharged or effused as the vapor-molecule evaporated from the inside of the crucible 1. Also, the change is very small in the heat capacity of content within the crucible 1. For this reason, the control upon heating temperature of the effusion material 5 is very easy, as well as, the control upon an amount of generation of the vapor molecule evaporated.

In the example mentioned in the above, the heat conduction medium 4 is contained within the crucible 1, being dispersed together with the effusion material 5 therein. On the contrary to this, as shown in FIG. 2, the effusion material 5 may be provided to cover the surface therewith, so as to be contained within the crucible 1, e.g. around the heat conduction medium 4 as the core. With doing so, since the heat conduction medium 4 is also heated at the same time when the effusion material 5 is heated through the crucible 1 by the heater 3, the temperature is equally distributed within the inside of the crucible 1, so that the effusion material 5 is heated uniformly therein, thereby to melt down to be evaporated.

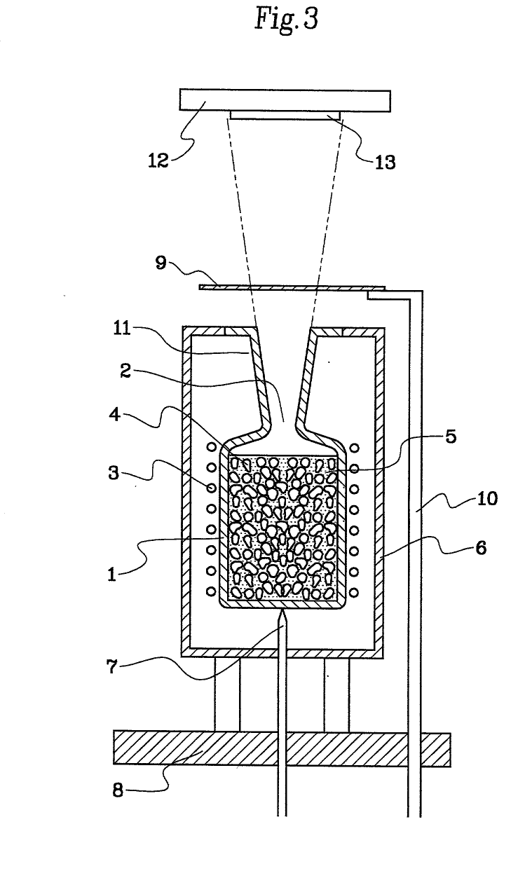

Next, explaining the molecular beam epitaxy effusion cell shown in FIG. 3, according to another embodiment of the present invention, wherein, also in this molecular beam epitaxy effusion cell is formed the draft portion 11 at a tip of the tapered vapor discharge opening 2 of the crucible 1, the inner diameter of which is gradually enlarged as it goes to the top thereof. However, this draft portion 11 is formed to be longer than that of the embodiment shown in the FIG. 1 mentioned above, and also is slower in the tapered angle thereof. With such the draft portion 11 as mentioned above, directivity is given to the vapor molecule evaporated and effused from the vapor discharge opening 2, so that a flow of the vapor molecule evaporated is formed, being uniform in density thereof in the direction restricted. With this, it is possible to grow the thin film(s) upon a film-forming surface restricted on the substrate, with high efficiency and with uniformity.

While we have shown and described several embodiments in accordance with our invention, it should be understood that the disclosed embodiments are susceptible of changes and modifications without departing from the scope of the invention. Therefore, we do not intend to be bound by the details shown and described herein but intend to cover all such changes and modifications falling within the ambit of the appended claims.

What is claimed is:

1. A molecular beam epitaxy effusion cell for use in vacuum thin film deposition, wherein effusion material is heated to melt down to be evaporated, so as to generate vapor-molecule for growth of a thin film thereof upon a solid body surface, comprising:
a crucible for containing the effusion material therein; and
a heating means for heating the effusion material contained within said crucible, wherein in said crucible is contained heat conduction medium, being stable thermally and chemically and having heat conductivity higher than that of said effusion material, together with said effusion material.

2. A molecular beam epitaxy effusion cell, as defined in the claim 1, wherein the heat conduction medium is made of a high heat conduction material, including at least one of pyrolytic boron nitride, silicon carbide, and aluminum-nitride.

3. A molecular beam epitaxy effusion cell, as defined in the claim 1, wherein said heat conduction medium is in granular-like form.

4. A molecular beam epitaxy effusion cell, as defined in the claim 1, wherein said heat conduction medium is made from the material same to that of said crucible.

5. A molecular beam epitaxy effusion cell, as defined in the claim 1, wherein the heat conduction medium is provided to cover around the effusion material in granular-like form.

6. A molecular beam epitaxy effusion cell, as defined in the claim 1, wherein said heat conduction medium contained in said crucible is mixed with said effusion material at around 70%:30% in volume ratio therebetween.

7. A molecular beam epitaxy effusion cell, as defined in the claim 1, wherein said heating means is provided around periphery of said crucible, so as to cover therewith.

8. A molecular beam epitaxy effusion cell, as defined in the claim 1, wherein said crucible has a horn-like draft portion formed at a top of said crucible.

9. A molecular beam epitaxy effusion cell, as defined in the claim 8, wherein the horn-like draft portion of said crucible is tapered to be narrowed at a top of a cylindrical main body of said crucible, and is gradually widened in diameter thereof upward.

10. A molecular beam epitaxy effusion cell, as defined in the claim 1, wherein said effusion material includes an organic electro luminescence material.

11. A method of molecular beam epitaxy effusion for use in vacuum thin film deposition, comprising the following steps:
preparing effusion material in granular-like form;
containing said effusion material together with heat conduction material within a crucible;
heating said crucible, so as to evaporate said effusion material therein; and
effusing said effusion material evaporated within said crucible onto a surface of a solid body to be deposited in form of a film.

12. A method of molecular beam epitaxy effusion, as defined in the claim 11, wherein said effusion material includes an organic electro luminescence material.

13. A method of molecular beam epitaxy effusion, as defined in the claim 11, wherein said heat conduction medium is in granular-like form.

14. A method of molecular beam epitaxy effusion, as defined in the claim 11, wherein the heat conduction medium is made of a high heat conduction material, including at least one of pyrolytic boron nitride, silicon carbide, and aluminum-nitride.

15. A method of molecular beam epitaxy effusion, as defined in the claim 11, wherein said heat conduction medium is made from the material same to that of said crucible.

16. A method of molecular beam epitaxy effusion, as defined in the claim 11, wherein the heat conduction medium is provided to cover around the effusion material in granular-like form.

17. A method of molecular beam epitaxy effusion, as defined in the claim 11, wherein said heat conduction medium contained in said crucible is mixed with said effusion material at around 70%:30% in volume ratio therebetween.
